(19) United States
(12) Patent Application Publication
(10) Pub. No.: US 2014/0326990 A1
(43) Pub. Date: Nov. 6, 2014

(54) ARRAY SUBSTRATE, METHOD FOR FABRICATING THE SAME AND DISPLAY DEVICE

(71) Applicant: BOE TECHNOLOGY GROUP CO., LTD., Beijing (CN)

(72) Inventors: Dongfang Wang, Beijing (CN); Liangchen Yan, Beijing (CN)

(21) Appl. No.: 14/241,602

(22) PCT Filed: Jun. 7, 2013
(86) PCT No.: PCT/CN2013/076960

§ 371 Date: Feb. 27, 2014

(30) Foreign Application Priority Data
Mar. 19, 2013 (CN) 201310086958.2

(51) Int. Cl. H01L 27/12

(52) U.S. Cl. CPC H01L 27/1225; H01L 27/1259
USPC 257/43; 438/104

(57) ABSTRACT

Embodiments of the invention relate to an array substrate, a method for fabricating the same and a display device. The method for fabricating the array substrate includes: forming a pattern of an etch stop layer on an active layer and a gate insulation layer not covered by the active layer; forming a pattern of a source/drain electrode layer on the etch stop layer; forming a patterning of a color filter layer on the source/drain electrode layer and the etch stop layer not covered by the source/drain electrode layer.

### FIELD OF THE ART

The invention relates to the field of display technologies, more particularly, to an array substrate, a method for fabricating the same and a display device.

### BACKGROUND

Active Matrix Organic Light Emitting Diode (AMOLED) is referred to as the next generation display technology. The AMOLED combines white LED technology together with Color Filter on Array (COA) technology which integrates a color filter film with an array substrate and has the advantages of faster response, higher contrast ratio, wide viewing angle and so on.

The array substrate in the COA technology typically comprises a substrate, a gate electrode, a gate insulation layer, an oxide active layer, an etch stop layer, a source/drain electrode layer, an inorganic passivation layer, a color filter layer, a resin layer and a pixel electrode layer.

As illustrated in FIG. 1, in a COA array substrate, the gate electrode 11 is in contact with the substrate 10, the gate insulation layer 12 is in contact with the gate electrode 11 and a portion of the substrate 10 not covered by the gate electrode, the oxide active layer 13 is in contact with the gate insulation layer 12. The etch stop layer 14 is in contact with the oxide active layer 13 and a portion of the gate insulation layer 12 not covered by the oxide active layer 13. The source/drain electrode layer 15 is in contact with the etch stop layer 14. The inorganic passivation layer 16 is formed on the source/drain electrode layer 15 and the stop layer 14 and configured for further blocking water vapor and hydrogen from affecting the oxide active layer 13. The color filter layer 17 is formed on the inorganic passivation layer 16, the resin layer 18 is formed on the color filter layer 17 and the pixel electrode layer 19 is formed on the resin layer 18. The key ingredient of the etch stop layer 14 comprised in the COA array substrate is silicon dioxide and the etch stop layer 14 is principally for protecting the oxide active layer 13 from being etched by subsequent etch processes. The key ingredient of the inorganic passivation layer 16 is silicon nitride for preventing water vapor and hydrogen from affecting the oxide active layer 13 and preventing the patterning process from damaging the oxide active layer 13. The key ingredient of the resin layer 18 is made of resin and configured for preventing water vapor and hydrogen from affecting both the color filter layer 17 and the oxide active layer 13.

During the procedure of fabricating the COA array substrate, each layer has to be undergone a patterning process according to its shape and position after the layer of material is formed. As the patterning process involves mostly photolithography and etching, it takes a long time to performing the patterning process.

Therefore, a plurality of material layers has to be formed when fabricating the COA array substrate using conventional technologies, and a patterning process is required for each material layer, which makes the fabrication process complicated and pricy.

### SUMMARY

Embodiments of the invention provide an array substrate and a method for fabricating the same and a display device.

A first aspect of the invention provides a method for fabricating an array substrate, the method comprises:

forming a pattern of an etch stop layer on an active layer and a gate insulation layer not covered by the active layer;

forming a pattern of a source/drain electrode layer on the etch stop layer;

forming a pattern of a color filter layer on the source/drain electrode layer and the etch stop layer not covered by the source/drain electrode layer.

A second aspect of the invention provides an array substrate comprising an active layer, an etch stop layer, a source/drain electrode layer and a color filter layer;

The active layer is in contact with the etch stop layer, the etch stop layer is in contact with the source/drain electrode layer, the source/drain electrode layer is in contact with the etch stop layer not covered by the source/drain electrode layer and the color filter layer.

A third aspect of the invention provides a display device comprising the above array substrate,

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 schematically illustrates a configuration of a conventional array substrate;

FIG. 2 schematically illustrates a flow chart of fabricating an array substrate in accordance with an embodiment of the invention;

FIG. 3 schematically illustrates a flow chart of fabricating an array substrate using both silicon dioxide and silicon nitride as an etch stop layer in accordance with an embodiment of the invention;

FIG. 4 schematically illustrates a procedure of fabricating an array substrate using silicon dioxide and silicon nitride as an etch stop layer in accordance with an embodiment of the invention;

FIG. 5 schematically illustrates a partial configuration of a single-gate array substrate in accordance with an embodiment of the invention; and

FIG. 6 schematically illustrates a configuration of a single-gate array substrate in accordance with an embodiment of the invention.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

In accordance with an embodiment of the invention, a color filter layer is directly formed on a source/drain electrode layer and an etch stop layer not covered by the source/drain electrode layer, thus the need of forming an inorganic passivation layer can be eliminated. As a result, the process procedure of depositing and patterning the inorganic passivation layer is omitted in the fabrication of the COA array substrate, thereby simplifying the fabrication process of the array substrate.

In the following, the embodiment of the invention will be described in detail with reference to the figures.

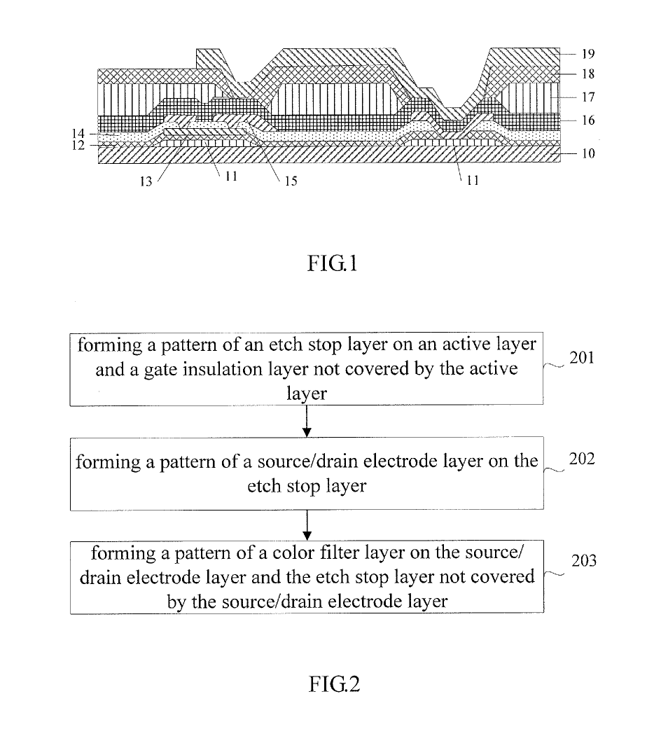

Illustrated in FIG. 2 is a method for fabricating the array substrate in accordance with the embodiment of the invention. The method comprises:

Step 201: forming a pattern of an etch stop layer on an active layer and a gate insulation layer not covered by the active layer;

Step 202: forming a pattern of a source/drain electrode layer on the etch stop layer;

Step 203: forming a patterning of a color filter layer on the source/drain electrode layer and the etch stop layer not covered by the source/drain electrode layer.

As an example, step 201 comprises depositing an etch stop layer on an active layer and a gate insulation layer not covered by the active layer and patterning the etch stop layer through a patterning process. The etch stop layer is for example made of a lamination comprising at least one of silicon dioxide and aluminum oxide and at least one of silicon nitride and silicon oxynitride.

As the composition ingredient of the etch stop layer is varied, the silicon dioxide and aluminum oxide are mainly for preventing the active layer from being etched, the silicon nitride is mainly for preventing water vapor and hydrogen from affecting the active layer, and the silicon oxynitride is mainly for preventing the active layer from being etched and preventing water vapor and hydrogen from affecting the active layer. Moreover, the etch stop layer is formed by a lamination with at least two of the above compounds, it thus can not only prevent the active layer from being etched but also prevent water vapor and hydrogen from affecting the active layer. As a result, it can prevent the active layer from being etched and prevent water vapor and hydrogen from affecting the active layer without forming the inorganic passivation layer, thereby ensuring a better property for the metal oxide semiconductor TFT in the panel and eliminating the fabrication process for the inorganic passivation layer.

For example, the etch stop layer is made of silicon dioxide with a thickness of 200 nm and silicon nitride of 100 nm thick, or is made of silicon dioxide of 200 nm thick and silicon oxynitride of 100 nm thick, or is made of silicon dioxide of 200 nm thick, silicon nitride of 100 nm thick and silicon oxynitride of 100 nm thick. As an example, the etch stop layer may also be made of aluminum oxide and silicon nitride, or is made of aluminum oxide and silicon oxynitride, or is made of aluminum oxide, silicon nitride and silicon oxynitride.

The thickness of each compound layer deposited on the active layer and the gate insulation layer not covered by the gate insulation layer may be designed as required, for example between 20 nm to 300 nm. As an example, individual compound layers are deposited under a temperature of 150° C. to 390° C.

As an example, step 202 comprises depositing a source/drain electrode layer on the patterned etch stop layer and patterning the source/drain electrode layer through a patterning process.

Preferably, in step 202, the color filter developer contains KOH, which is corrosive to metals like aluminum, therefore an anti-alkaline corrosion metal is needed when depositing the source/drain electrode layer. For example, anti-alkaline corrosion metals such as molybdenum (Mo), copper (Cu), moly-tungsten (MoW), or indium tin oxide (ITO) are used to deposit the source/drain electrode layer.

As an example, step 203 comprises depositing a color filter layer on the source/drain electrode layer and the etch stop layer not covered by the source/drain electrode layer and patterning the color filter layer through a patterning process.

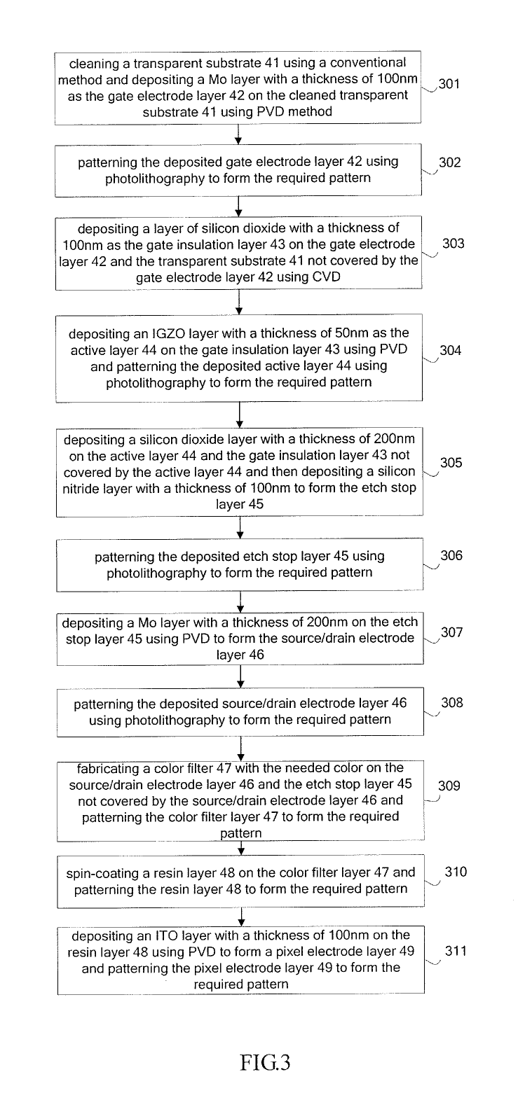

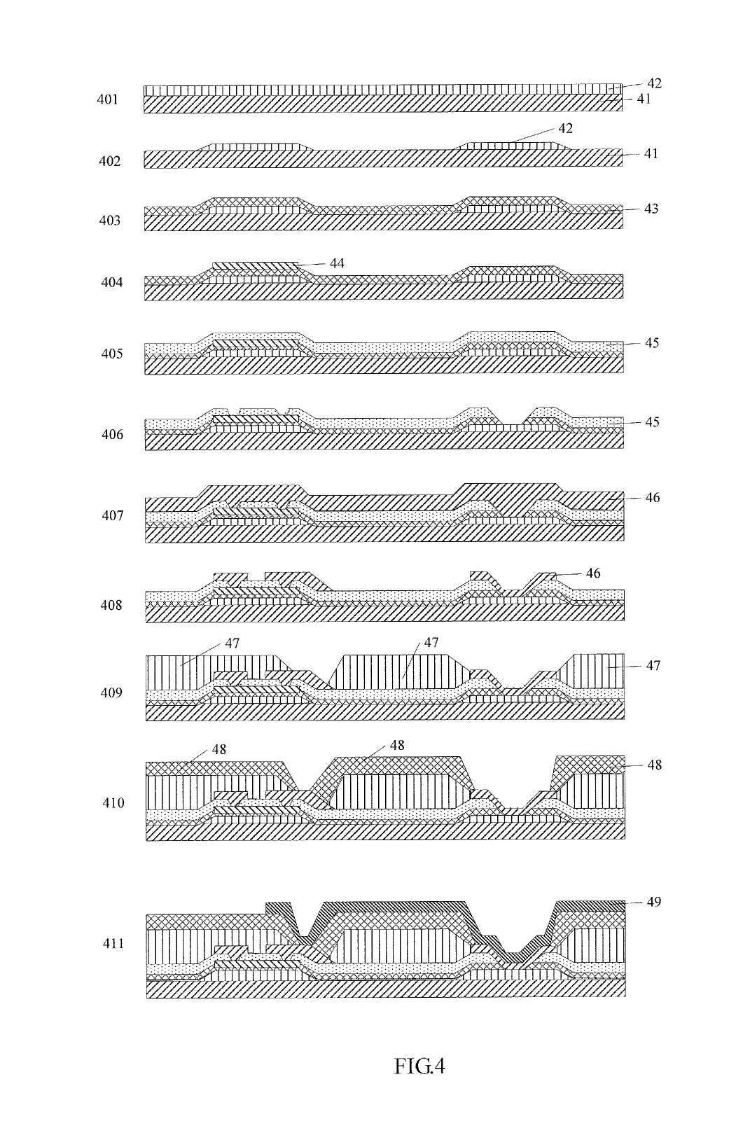

FIG. 3 illustrates a method of fabricating an array substrate using both silicon dioxide and silicon nitride as an etch stop layer in accordance with an embodiment of the invention, FIG. 4 schematically illustrates configurations of the array substrate corresponding to each step of FIG. 3. The method for fabricating the array substrate in accordance with the embodiment of the invention comprises:

Step 301: cleaning a transparent substrate 41 using a conventional method and depositing a Mo layer with a thickness of 100 nm as the gate electrode layer 42 on the cleaned transparent substrate 41 using Physical Vapor Deposition (PVD) method. For detail of a schematic configuration corresponding to step 301 please refer to 401 of FIG. 4.

Step 302: patterning the deposited gate electrode layer 42 using photolithography to form the required pattern. For detail of a schematic configuration corresponding to step 302 please refer to 402 of FIG. 4.

Step 303: depositing a layer of silicon dioxide with a thickness of 100 nm as the gate insulation layer 43 on the gate electrode layer 42 and the transparent substrate 41 not covered by the gate electrode layer 42 using Chemical Vapor Deposition (CVD). For detail of a schematic configuration corresponding to step 303 please refer to 403 of FIG. 4.

Step 304: depositing an indium gallium zinc oxide (IGZO) layer with a thickness of 50 nm as the active layer 44 on the gate insulation layer 43 using PVD and patterning the deposited active layer 44 using photolithography to form the required pattern. For detail of a schematic configuration corresponding to step 304 please refer to 404 of FIG. 4.

Step 305: depositing a silicon dioxide layer with a thickness of 200 nm on the active layer 44 and the gate insulation layer 43 not covered by the active layer 44 using PVD, and then depositing a silicon nitride layer with a thickness of 100 nm to form the etch stop layer 45. For detail of a schematic configuration corresponding to step 305 please refer to 405 of FIG. 4.

Step 306: patterning the deposited etch stop layer 45 using photolithography to form the required pattern. For detail of a schematic configuration corresponding to step 306 please refer to 406 of FIG. 4.

Step 307: depositing a Mo layer with a thickness of 200 nm on the etch stop layer 45 using PVD to form the source/drain electrode layer 46. For detail of a schematic configuration corresponding to step 307 please refer to 407 of FIG. 4.

Step 308: patterning the deposited source/drain electrode layer 46 using photolithography to form the required pattern. For detail of a schematic configuration corresponding to step 308 please refer to 408 of FIG. 4.

Step 309: fabricating a color filter layer 47 with the needed color on the source/drain electrode layer 46 and the etch stop layer 45 not covered by the source/drain electrode layer 46 and patterning the color filter layer 47 to form the required pattern. For detail of a schematic configuration corresponding to step 309 please refer to 409 of FIG. 4.

Step 310: spin-coating a resin layer 48 on the color filter layer 47 and patterning the resin layer 48 to form the required pattern. For detail of a schematic configuration corresponding to step 310 please refer to 410 of FIG. 4.

Step 311: depositing an ITO layer with a thickness of 100 nm on the resin layer 48 using PVD to form a pixel electrode layer 49 and patterning the pixel electrode layer 49 to form the required pattern. For detail of a schematic configuration corresponding to step 311 please refer to 411 of FIG. 4.

As an example, in step 301, the transparent substrate 41 may be cleaned using conventional cleaning method, or using acid-alkali method or weak alkali method.

In step 301, the gate electrode layer 42 may also be obtained via evaporation method, and the thickness of the gate electrode layer may be 50 nm to 400 nm.

The thickness of the gate insulation layer in step 303 may be 100 nm to 500 nm. The gate insulation layer is made of at least one of the following compounds: silicon nitride, silicon oxynitride, silicon dioxide, aluminum oxide, aluminum oxynitride. As an example, when the gate insulation layer is made of two or more of the above compounds, the gate insulation layer has a lamination structure. For example, when the gate insulation layer is made of silicon nitride, silicon oxynitride, and silicon dioxide, first a silicon nitride layer is deposited, then a silicon oxynitride layer, and finally a silicon dioxide layer, thereby forming the gate insulation layer. The various layers may also take another order, which will not be elaborated here.

In step 304, the deposition thickness of the oxide active layer may be 10 nm to 80 nm, and the material of the oxide active layer 44 may include but not limit to the following compounds: ITZO (Indium Tin Zinc Oxide), HIZO (Hafnium Indium Zinc Oxide), ZnO, SnO, SnO2, Cu2O, ZnNO.

In step 307, the thickness of the source/drain electrode layer may be 50 nm to 400 nm.

In step 309, colors arrangement of the color filters in the color filter layer may vary with different type of array substrate. For example, the color filter layer is fabricated with an order of R(red), G(green), B(blue), or with an order of R, G, B, W(white); and the thickness of the color filter layer is 2˜4 μm.

In step 310, the resin layer 48 is for preventing water vapor in the air from entering the array substrate. Moreover, the resin layer 48 is formed to flatten the substrate surface. The thickness of the resin layer may be 1.5˜5 μm.

In step 311, the thickness of the ITO pixel electrode layer 49 may be 40 nm to 150 nm.

Illustrated in FIG. 5 is a partial configuration of a single-gate array substrate in accordance with an embodiment of the invention. The array substrate comprises an active layer 51, an etch stop layer 52, a source/drain electrode layer 53 and a color filter layer 54.

The active layer 51 is in contact with the etch stop layer 52, the etch stop layer 52 is in contact with the source/drain electrode layer 53, the source/drain electrode layer 53 is in contact with the etch stop layer 52 not covered by the source/drain electrode layer and contact with the color filter layer 54.

As an example, a method for fabricating the single-gate array substrate of FIG. 5 comprises: depositing an etch stop layer 52 on an active layer 51 and a gate insulation layer not covered by the active layer and patterning the etch stop layer 52 through a patterning process; depositing a source/drain electrode layer 53 on the patterned etch stop layer 52 and patterning the source/drain electrode layer through a patterning process; depositing a color filter layer 51 on the source/drain electrode layer 53 and the etch stop layer 52 not covered by the source/drain electrode layer and patterning the color filter layer 51 through a patterning process. The etch stop layer 52 is for example made of a lamination comprising at least one of silicon dioxide and aluminum oxide and at least one of silicon nitride and silicon oxynitride.

The thickness of individual laminated layers in the etch stop layer 52 may be designed as required, for example between 20 nm to 300 nm.

As the color filter developer contains KOH, which is corrosive to metals like aluminum, therefore an anti-alkaline corrosion metal is used for the source/drain electrode layer such as molybdenum (Mo), copper (Cu), moly-tungsten (MoW), or indium tin oxide (ITO).

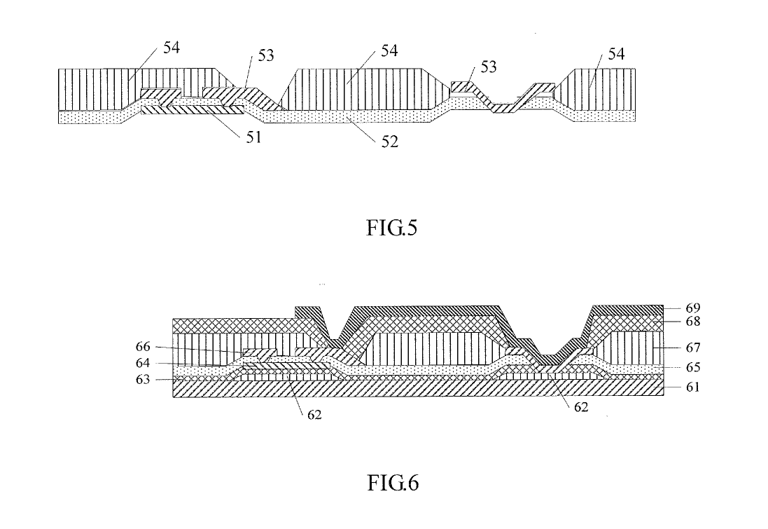

FIG. 6 schematically illustrates a configuration of a single-gate array substrate in accordance with an embodiment of the invention. The array substrate comprises a transparent substrate 61, a gate electrode 62, a gate insulation layer 63, an active layer 64, an etch stop layer 65, a source/drain electrode layer 66, a color filter layer 67, a resin layer 68 and a pixel electrode layer 69.

The transparent substrate 61 is in contact with the gate electrode 62, the gate insulation layer 63 overlays the gate electrode 62 and the transparent substrate 61 not covered by the gate electrode; the active layer 64 is in contact with the gate insulation layer 63, the etch stop layer 65 overlays the active layer 64 and the gate insulation layer 63 not covered by the active layer; the source/drain electrode layer 66 is in contact with the etch stop layer 65, the color filter layer 67 overlays the source/drain electrode layer 66 and the etch stop layer 65 not covered by the source/drain electrode layer; the resin layer 68 overlays the color filter layer 67; the pixel electrode layer 69 overlays the resin layer 68 and is in contact with the resin layer as well as the source/drain electrode layer not covered by each of the resin layer and the color filter layer.

Individual layers of the array substrate may have thicknesses as following: the thickness of the gate electrode 62 is 50 nm-400 nm, the thickness of the gate insulation layer 63 is 100 nm-500 nm, the thickness of the active layer 64 is 10 nm-80 nm, the thickness of the source/drain electrode layer 66 is 50 nm-400 nm, and the thickness of the pixel layer 69 is 50 nm-150 nm.

The configuration of a dual-gate array substrate or a plural-gate array substrate is similar to that of the single-gate array substrate and will not be elaborated here.

An embodiment of the invention further provides a display device comprising the array substrate as illustrated in FIG. 5 or FIG. 6.

According to the embodiment of the invention, the pattern of the etch stop layer is formed on the active layer and the gate insulation layer not covered by the active layer; the pattern of the source/drain electrode layer is formed on the etch stop layer; the pattern of the color filter layer is formed on the source/drain electrode layer and the etch stop layer not covered by the source/drain electrode layer. In the embodiment of the invention, as the pattern of the color filter layer is directly formed on the source/drain electrode layer and the etch stop layer not covered by the source/drain electrode layer, the need for the inorganic passivation layer can be eliminated. As a result, the process procedures of depositing and patterning the inorganic passivation layer are omitted in the fabrication of the COA array substrate, thereby simplifying the fabrication process of the array substrate.

What are described above is related to the illustrative embodiments of the disclosure only and not limitative to the scope of the disclosure; the scopes of the disclosure are defined by the accompanying claims.

1. A method for fabricating an array substrate, the method comprises:
forming a pattern of an etch stop layer on an active layer and a gate insulation layer not covered by the active layer;
forming a pattern of a source/drain electrode layer on the etch stop layer; and
forming a pattern of a color filter layer on the source/drain electrode layer and the etch stop layer not covered by the source/drain electrode layer.

2. The method of claim 1, wherein the method further comprises:
depositing an etch stop layer on an active layer and a gate insulation layer not covered by the active layer and patterning the etch stop layer through a patterning process;
depositing a source/drain electrode layer on the patterned etch stop layer and patterning the source/drain electrode layer through a patterning process;
depositing a color filter layer on the patterned source/drain electrode layer and the etch stop layer not covered by the source/drain electrode layer and patterning the color filter layer through a patterning process.

3. The method of claim 1, wherein the etch stop layer is made of a lamination comprising at least one of silicon dioxide and aluminum oxide and at least one of silicon nitride and silicon oxynitride.

4. The method of claim 3, wherein depositing the etch stop layer on the active layer and the gate insulation layer not covered by the active layer comprises:
depositing the etch stop layer having individual layer of 20 nm to 300 nm in thickness corresponding to individual compound on the active layer and the gate insulation layer not covered by the active layer.

5. The method of claim 3, wherein depositing the etch stop layer on the active layer and the gate insulation layer not covered by the active layer comprises:
depositing the etch stop layer on the active layer and the gate insulation layer not covered by the active layer under a temperature of 150° C. to 390° C.

6. The method of claim 1, wherein the active layer is an oxide active layer.

7. The method of claim 1, wherein the source/drain electrode layer is made of an anti-alkaline corrosion metal.

8. The method of claim 7, wherein the anti-alkaline corrosion metal comprises any of molybdenum, moly-tungsten, copper and indium tin oxide.

9. An array substrate comprising an active layer, an etch stop layer, a source/drain electrode layer and a color filter layer, wherein, the active layer is in contact with the etch stop layer, the etch stop layer is in contact with the source/drain electrode layer, the source/drain electrode layer is in contact with the etch stop layer not covered by the source/drain electrode layer and the color filter layer.

10. The array substrate of claim 9, wherein the array substrate further comprises a substrate, a gate electrode, a gate insulation layer, a resin layer and a pixel electrode layer, wherein,
the gate electrode is in contact with the substrate, the gate insulation layer is in contact with the gate electrode and the substrate not covered by the gate electrode, the active layer is in contact with the gate insulation layer, the etch stop layer is in contact with the active layer and the gate insulation layer not covered by the active layer, the source/drain electrode layer is in contact with the etch stop layer, the color filter layer is in contact with the source/drain electrode layer and the etch stop layer not covered by the source/drain electrode layer, the resin layer is in contact with the color filter layer, and the pixel electrode layer is in contact with the resin layer.

11. The array substrate of claim 9, wherein the etch stop layer is made of a lamination comprising at least one of silicon dioxide and aluminum oxide and at least one of silicon nitride and silicon oxynitride.

12. The array substrate of claim 11, wherein each compound layer in the etch stop layer has a thickness of 20 nm to 300 nm.

13. The array substrate of claim 9, wherein the active layer is an oxide active layer.

14. The array substrate of claim 9, wherein the source/drain electrode layer is made of an anti-alkaline corrosion metal.

15. The array substrate of claim 14, wherein the anti-alkaline corrosion metal comprises any of molybdenum, moly-tungsten, copper and indium tin oxide.

16. A display device comprising the array substrate of claim 9.

17. The method of claim 2, wherein the etch stop layer is made of a lamination comprising at least one of silicon dioxide and aluminum oxide and at least one of silicon nitride and silicon oxynitride.
